(19) United States
(12) Patent Application Publication
(10) Pub. No.: US 2012/0313705 A1
(43) Pub. Date: Dec. 13, 2012

(54) Method for introducing feedback in a FET amplifier

(76) Inventor: Colin Shaw, Rogers, AR (US)

(21) Appl. No.: 13/158,448

(22) Filed: Jun. 12, 2011

(51) Int. Cl. H03F 3/45; H03F 1/22

(52) U.S. Cl. 330/260

(57) ABSTRACT

A method of configuring a FET amplifier with two inputs demonstrating similar-phased response to similar-phased inputs. One input can be used as a feedback path in suitable amplifier circuits, improving frequency performance by decreasing feedback resistance. The second input provides the means for a high impedance connection to a drive signal. The present invention is particularly applicable to applications involving constant voltage sources and constant current active sources with or without cascoding, in both single-ended and differential configurations.

### BACKGROUND OF THE INVENTION

There are several methods currently used to develop feedback in an amplifier. One technique is to use a differential pair to accommodate negative feedback by using one side of the differential pair for a single-ended input and the other as a feedback path. This can be accomplished directly, as illustrated by U.S. Pat Nos. #4,107,619, #4,188,588 and #5,260,672, or more abstractly in high gain amplifiers vis-a-vis well known operational amplifier feedback methods. Both of these methods require numerous active devices in the form of current sources, current mirrors, gain stages, and the initial differential pair itself In addition to the employment of numerous active devices, high gain amplifiers used in the manner of operational amplifiers suffer the problem of relatively low input resistance and relatively high feedback resistance.

### BRIEF SUMMARY OF THE INVENTION

The present invention depicts a method of configuring FET-based amplifiers in a current balancing circuit that allows for two direct gate inputs demonstrating arbitrary shunted input resistance and low series gate resistance. Used in a circuit with an output signal that is out of phase with the input, negative feedback can be introduced into the circuit while utilizing minimal active circuit components and simultaneously raising the input impedance and decreasing the feedback path impedance. The realization of this invention is an amplifier with decreased distortion and lowered output impedance with improved frequency performance.

### BRIEF DESCRIPTION OF THE DRAWINGS

FIG. 1: Illustration of invention using N-channel MOSFETs with a constant current source.

FIG. 2: Illustration of invention using N-channel JFETs with a constant current source.

FIG. 3: Illustration of invention using P-channel MOSFETs with a constant current source.

FIG. 4: Illustration of invention using P-channel JFETs with a constant current source.

FIG. 5: Illustration of the invention using N-channel MOSFETs in a cascode configuration with a constant current source.

FIG. 6: Illustration of the invention in a differential application using N-channel MOSFETs in a cascode configuration with constant current sources.

### DETAILED DESCRIPTION OF THE INVENTION

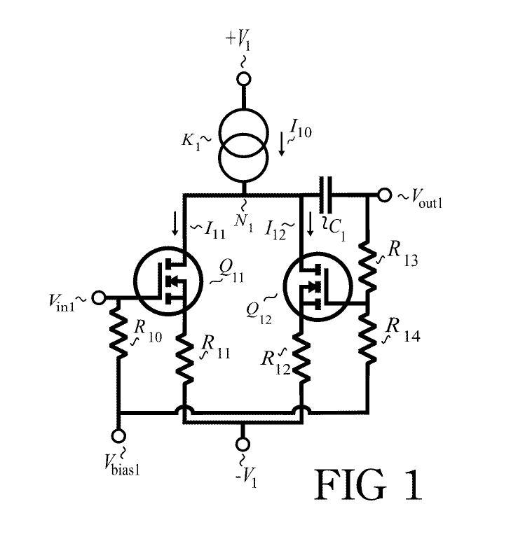

The topology of the amplifier depicted in FIG. 1 comprises a symmetrical arrangement of similar N-channel MOSFETs Q₁₁ and Q₁₂. A constant current source K₁, fed by power supply +V₁, produces a current I₁₀ that is divided as evenly as is practical in the quiescent state between the two N-channel MOSFETs Q₁₁ and Q₁₂ at node N₁, resulting in channel currents I₁₁ and I₁₂, respectively. It should be appreciated by those trained in the art that, while the invention is demonstrated by way of example using active, constant current sources, effects consistent with the spirit of the present invention can be achieved with constant voltage sources. Source resistors R₁₁ and R₁₂ have an induced voltage I₁₁R₁₁ and I₁₂R₁₂ that biases Q₁₁ and Q₁₂, respectively, resulting in, effectively, a two transistor degenerated amplifier with resistors R₁₁ and R₁₂ terminating in power supply −V₁. R₁₁ and R₁₂ are typically similar in value, though gate-source offset variations in Q₁₁ and Q₁₂ can be accommodated with small relative changes in the values of R₁₁ and R₁₂. R₁₁ and R₁₂ may be omitted depending on the operating characteristics of transistors Q₁₁ and Q₁₂. The gate of Q₁₁ is connected to a bias voltage V_{bias1} by an input resistor R₁₀, where V_{bias1} is a common reference point for the input Vᵢₙ₁ and the output Vₒᵤₜ₁. Given the high impedance of the gate of Q₁₁, R₁₀ is effectively the input impedance experienced by the source Vᵢₙ₁.

Capacitor C₁ provides quiescent DC immunity from the voltage at node N₁ to the resistor divider network comprised of resistors R₁₃ and R₁₄. Those trained in the art will observe that, notwithstanding the effects of transistor Q₁₂, the amplifier comprising constant current source K₁ and transistor Q₁₁ will create an amplified, out of phase signal at terminal Vₒᵤₜ₁. The gate of transistor Q₁₂ is driven out of phase from the input the magnitude of which is selectable by the values of resistors R₁₃ and R₁₄. Negative feedback is injected at the gate of Q₁₂, manifesting as negative feedback in the cumulative current I₁₁+I₁₂ and the resultant voltage at node N₁.

Signal variations driven by input Vᵢₙ₁ manifest as output Vₒᵤₜ₁, as node N₁ observes deviations between constant current I₁₀ and cumulative transistor current I₁₁+I₁₂. This results in a change in the voltage at node N₁ and induces output voltage Vₒᵤₜ₁ across the total load resistance, which is R₁₃+R₁₄ in parallel with any external load resistance. The series resistance of R₁₃ and R₁₄ is chosen to reflect minimal change of the total load resistance when the external load is applied while simultaneously being as low in value as possible to reduce the deleterious effects of the gate capacitance of Q₁₂. The value of C₁ at frequencies of interest must be chosen such that the reactance of C₁ is small compared with the total load resistance.

It should be noted that the feedback network formed by decoupling capacitor C₁ and resistors R₁₃ and R₁₄ is not specific to the present invention. Any feedback network, passive or active, accomplishing the objective of introducing an out of phase signal at the gate of Q₁₂ originating at node N₁ that is consistent with the DC operating parameters of the amplifier given specific choices of power supplies +V₁ and −V₁, currents I₁₀, I₁₁ and I₁₂, source resistors R₁₁ and R₁₂, gate bias voltage V_{bias1}, and transistor types Q₁₁ and Q₁₂, accomplishes the claims of the present invention. The network shown, being versatile with respect to application, is a preferred embodiment of the use of the invention in a practical circuit.

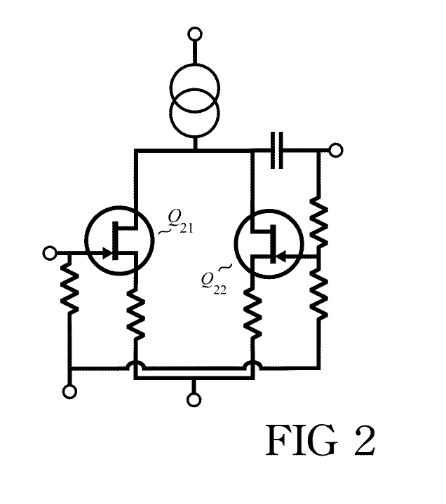

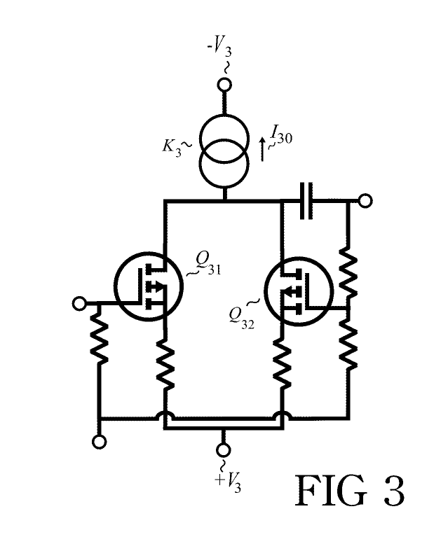

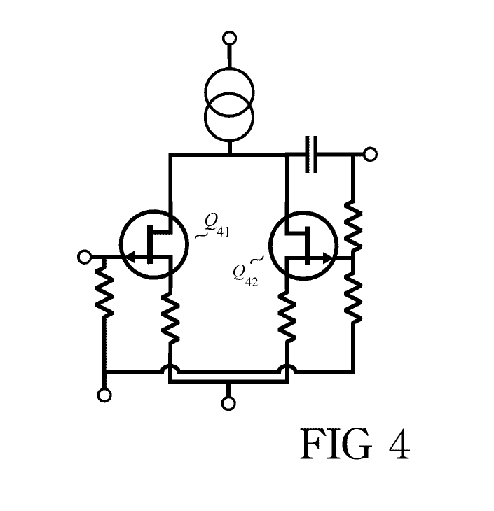

FIG. 2 depicts a claimed topology of the present invention that is identical except for transistors Q₂₁ and Q₂₂ being replaced by N-channel JFETs. FIG. 3 depicts a claimed topology involving P-channel MOSFETs Q₃₁ and Q₃₂. In this illustration it should be noted that, relative to the similarly drawn circuits previously presented, power supplies +V₃ and −V₃ are reversed. Furthermore, the active constant current source K₃ induces a current I₃₀ that is reverse the complimentary topology. FIG. 4 depicts the present invention using P-channel JFETs Q₄₁ and Q₄₂.

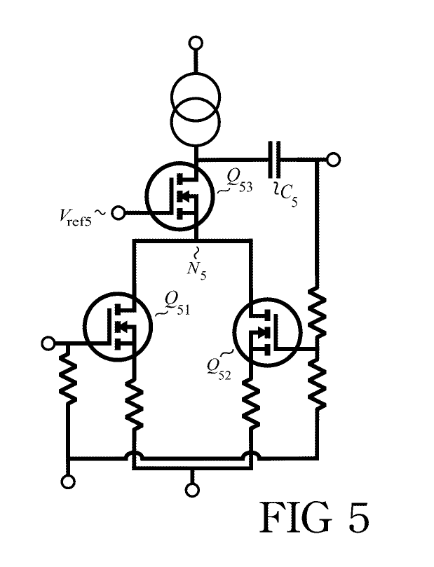

The amplifier is further improved in FIG. 5 with the addition of a cascode stage comprising transistor Q₅₃ and associated gate bias voltage V_{ref5}. As a result, capacitor C₅ decouples the drain of Q₅₃ rather than node N₅. Those trained in the art will recognize the enhanced benefit of this arrangement vis-a-vis improving frequency performance by decreasing the effective gate capacitance of transistors Q₅₁ and Q₅₂. While improved with respect to the mitigation of effective gate capacitance, this amplifier experiences the same relationship between values of external load resistance and capacitor C₅ with respect to frequency performance.

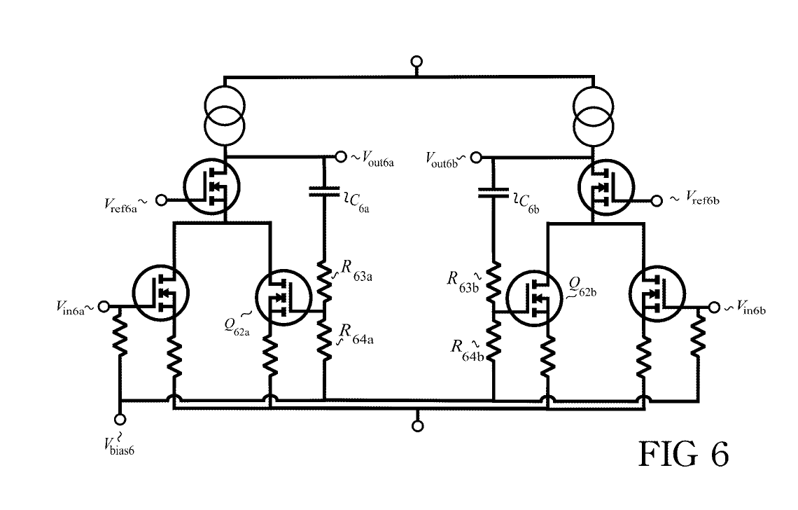

The amplifier is made differential as illustrated in FIG. 6 by combining two symmetrical copies of the amplifier depicted in FIG. 5. In this case the two halves of the resulting differential amplifier are identified by diagram suffixes a and b. The two halves of the amplifier are driven by inputs Vᵢₙ₆ₐ and V_{in6b} with signals that are out of phase with each other with respect to bias voltage V_{bias6}. This results in a differential signal output exhibiting voltages Vₒᵤₜ₆ₐ and V_{out6b}, respectively. The symmetrical arrangement of the differential amplifier allows the position of output decoupling capacitors C₆ₐ and C_{6b} to be altered such that the external load resistance is connected directly between terminal Vₒᵤₜ₆ₐ and V_{out6b}. Cascode transistor gate reference voltages V_{ref6a} and V_{ref6b} can be adjusted to null the quiescent voltage differential between Vₒᵤₜ₆ₐ and V_{out6b}. Since series resistance R₆₃ₐ+R₆₄ₐ (as well as R_{63b}+R_{64b}) is designed to be large compared to the external load resistance between terminals Vₒᵤₜ₆ₐ and V_{out6b}, the values of C₆ₐ and C_{6b} can be decreased from that of the non-differential variations of the invention while maintaining similar frequency performance. It is only the feedback to transistors Q₆₂ₐ and Q_{62b} that is effected by this change in topology (compared to that of transistor Q₅₂, FIG. 5, for example).

As with the amplifier topology depicted in FIG. 1, the amplifier topologies depicted in FIG. 5 and FIG. 6 are amenable to the transistor type alternatives presented in FIG. 2, FIG. 3 and FIG. 4 (namely N-channel JFETs, P-channel MOSFETs and P-channel JFETs). FIG. 5 and FIG. 6 are illustrated as exemplars of these alternatives while abiding the spirit of the present invention.

What I claim as my invention is:

1. A method of configuring a FET amplifier with two inputs having similar-phased response at an output, where the transistors comprising the input stage share at least one common element that may be the source, the drain, or both, and the purpose of the configuration is injection of feedback at one of the inputs.

2. The method according to claim 1, wherein the configuration consists of two N-channel JFETs.

3. The method according to claim 1, wherein the configuration consists of two P-channel JFETs.

4. The method according to claim 1, wherein the configuration consists of two N-channel MOSFETs.

5. The method according to claim 1, wherein the configuration consists of two P-channel MOSFETs.

6. The method according to claim 1, wherein the configuration is used in conjunction with a constant voltage power source.

7. The method according to claim 1, wherein the configuration is used in conjunction with a constant current power source.

8. The method according to claim 1, wherein the configuration is used in a cascode amplifier arrangement with a constant voltage power source.

9. The method according to claim 1, wherein the configuration is used in a cascode amplifier arrangement with a constant current power source.

10. The method according to claim 6, wherein the configuration is employed with its dual to form a differential amplifier.

11. The method according to claim 7, wherein the configuration is employed with its dual to form a differential amplifier.

12. The method according to claim 8, wherein the configuration is employed with its dual to form to differential amplifier.

13. The method according to claim 9, wherein the configuration is employed with its dual to form a differential amplifier.
